(19) United States
(12) Patent Application Publication
(10) Pub. No.: US 2005/0065042 A1
(43) Pub. Date: Mar. 24, 2005

(54) Anti-corrosive engine oil system components

(75) Inventor: Derek Tarrant, Greeneville, TN (US)

Correspondence Address: Doreen J. Gridley;ICE MILLER, One American Square, Box 82001, Indianapolis, IN, 46282-0002, US

(73) Assignee: Alltrista Zinc Products, L.P., an Indiana limited partnership, Greeneville, TN (US)

(21) Appl. No.: 10/924,392

(22) Filed: Aug. 24, 2004

Related U.S. Application Data
(63) Continuation-in-part of application No. 10/667,587, filed on Sep. 22, 2003.

(51) Int. Cl. F16C 1/00; C23C 14/00

(52) U.S. Cl. 508/100; 204/192.12

(57) ABSTRACT

The present invention is an oil system component comprising and a method for its making, designed to neutralize acid by utilizing components comprising zinc or a zinc-coating. According to one embodiment, a multipurpose component is provided by spraying a standard component such as the oil sump, oil screen, and/or oil filter with a zinc plasma in an inert atmosphere to create an acid-neutralizing coating on the component. The present invention is particularly suited for incorporation into a standard oil filter by fabricating the casing and or an internal screen of zinc coated materials and/or by incorporating zinc coated product or materials into the mechanical filter material.

### BACKGROUND

This invention claims priority to patent application Ser. No. 10/667,587 to Tarrant, filed Sep. 22, 2003. This invention relates generally to the field of oil systems used in internal combustion engines.

Engine oil characteristics are constantly undergoing improvement so as to allow an increased interval between engine oil changes. Similarly, changes in the materials manufacturing processes of engine components have reduced the amount of wear products introduced into the engine oil, allowing an increased interval between engine oil changes. However, with the advent of exhaust gas recirculation in gasoline engines, and potentially for diesel engines, the introduction of acidic exhaust products into the lubricating oil of internal combustion engines has increased many fold. For example, sulphur compounds in internal combustion engines are oxidized in combustion to acidic sulphur dioxide.

The increase in acidic exhaust products, alone or in conjunction with water formed during the combustion process, causes corrosion of internal engine components and reduces the level of additives that are designed to decrease wear and improve performance under extreme pressures. Moreover, other sulphur compounds such as hydrogen sulphide and mercaptans are corrosive when they become incorporated into the engine oil (excess fuel conditions on cold start for example) in their original form and exacerbate the above problems when they become oxidized during combustion. This results in critical reduction of the concentration of the oil additives long before the oil is scheduled to be changed.

Inorganic neutralizing chemicals may be incorporated into the oil system so as to neutralize the acidic exhaust products. However, these neutralizing chemicals may not have consistent or reliable initial particle size distribution. Moreover, these chemicals tend to fracture or undergo other forms of particle reduction under conditions such as impact and/or vibration which are likely to be encountered in, or close to, an internal combustion engine. This may result in the undesired introduction of the salts into the oil pumping or bearing portions of the oil system.

Therefore, it is desirable in an engine oil system to provide a “component” that will neutralize acid introduced into the engine oil. It is desired that the component be compatible with existing oil systems and readily incorporated into new systems. It is further desired that the component be capable of use without the need to introduce additional parts to existent oil systems. It is also desired that the component be easily manufactured and not add significantly to the costs of production, maintenance, or repair of the component and/or oil system. Finally, it is desired that the component typically not fracture or undergo other reduction under conditions likely to be encountered in, or close to, an internal combustion engine.

### BRIEF SUMMARY OF THE INVENTION

The present invention comprises an oil system component which includes an anti-corrosive material such as zinc, magnesium, cadmium, or calcium. The component functions as a filter for acidic exhaust products (“acid filter”) through the use of the anti-corrosive material. When the anti-corrosive material contacts acidic combustion products within the lubricating oil, the acidic combustion products are neutralized. This saves engine corrosion and reduces the degradation of oil additives.

The anti-corrosive material must have a large enough mass and sufficient surface area in contact with the lubricating oil so that the corrosive contaminants can be effectively neutralized before they can substantially attack the internals of the engine or the oil additive package. By sacrificing a portion of the anti-corrosive material, corrosion is substantially reduced and the additive package is protected and can continue performing its intended function.

The benefits of the present invention may be realized in several embodiments. One such embodiment comprises the insertion of thin-gauge plain or perforated sheet in the oil path. For example, a zinc sheet may be located inside the oil filter canister, either separately or pleated with the paper element that comprises the oil filter. The sheet may be very thin, such as a foil, or a comparatively thicker sheet. As used herein, “oil filter” refers to the standard mechanical filtration components well known in the prior art. In order to increase surface area and reduce flow restriction, the foil can be punched with holes, perforated with slits or perforated and expanded into a mesh. This type of modified zinc foil can be loosely placed in an oil filter canister or it can become a more intimate part of the oil filter if used in combination with the porous (typically paper) oil filter media before it is pleated and fabricated into the oil filter element. Alternatively, the zinc foil may be placed in other locations within the oil system so long as there is sufficient contact with the oil. Such locations include the oil sump, oil cooler, or even an external oil processing device.

According to another embodiment of the invention, metallic fibers may be used. The fibers must be controlled and prevented from entering the “clean” side of the lubricating oil system and endangering sensitive bearing surfaces. Prevention of entry into the “clean” side can be accomplished by packing fibers into void spaces in the “dirty” side of a regular or by-pass oil filter where the oil filter element prevents their passage into sensitive areas of the engine. Alternatively, the metallic fibers can be used as an integral part of the oil filter media. The fibrous nature of the metallic fibers will allow it to be incorporated by wet laid or dry laid non-woven techniques to produce a cohesive media construction that binds the fibers firmly into the oil filter media where they can perform their function without becoming dislodged and entering the clean area of the oil system.

As in the case of a metallic sheet, the zinc fibers can be used in locations other than the oil filter. For example the fibers can be placed in the sump or other oil collection areas of the engine, provided the fibers are prevented from entering sensitive areas of the oil pumping and bearing system. Such immobilization can be realized by restraining them within a porous media that allows the passage of oil while preventing the egress of fibers. Alternatively, the fibers could be formed into a compressed fiber component, such as a briquette or compressed acid filter screen, that would hold the fibers secure by virtue of compression and entanglement. Use of such a compressed component allows the use of fibers in the sump, oil reservoir or external oil processing device.

Other embodiments of the present invention may include the use of metallic powder or incorporation of zinc components into the oil system. Zinc powder may be used in a manner similar to metallic fibers, although the powder cannot be formed by compression. Zinc powder may, however, be incorporated on the “dirty” side of the oil filter. Being robust, the zinc powder can be relied upon not to undergo particle size reduction that would produce particles small enough to pass through the oil filter media and damage bearing surfaces.

Metallic components within an internal combustion engine can be placed in contact with the lubricating oil. The components may be included solely for their intended neutralizing purpose (a “special purpose component”) or the component may be a standard component which also provides a neutralizing function (“multipurpose component”). For example the entire engine sump pan could be made from zinc. Alternatively, a zinc sheet could be fabricated into an oil screen, baffle or oil scraper device. Zinc could also be used to form the outer casing of a regular or by-pass oil filter or could comprise some of the internal metal components in the oil filter.

In another embodiment of the present invention, a method for coating components with zinc comprises the steps of using one or more electrodes comprising zinc, providing an electrical current to the electrode(s) so that a plasma comprising zinc is formed, and directing the plasma toward a component that is to be coated with zinc. The method can be used to coat oil filter components or other components of an oil system, such as an inner mesh, filter batting, oil screen, or oil scraper, so that those components are coated in zinc. Further, the method can be performed in an inert atmosphere.

According to another embodiment of the present invention, a coated oil screen is created by directing a plasma comprising zinc toward an oil screen so that the oil screen is coated. Additionally, the coated oil screen can be created by performing the above steps in an inert atmosphere. Further, the plasma comprising zinc can be formed by utilizing one or more electrodes comprising zinc and arcing an electrical current between the electrodes. Finally, the oil screen or material comprising an oil screen can be passed under the electrode(s) comprising zinc so that the material is constantly moving under the one or more electrodes and is evenly coated by the metal in plasma form.

Another embodiment of the present invention relates to a coated oil scraper created through the steps of directing a plasma comprising zinc toward an oil scraper to create an oil scraper with a coating comprising zinc. Alternatively, the coated oil scraper can be created as described above, but with the steps performed in an inert atmosphere. Further, the step of directing a plasma comprising zinc toward the oil scraper can be conducted by providing at least one electrode comprising zinc and providing an electrical current to the at least one electrode. Finally, the oil scraper can be presented under the at least one electrode via a conveyor belt.

According to another embodiment of the present invention, a coated oil scraper is created by providing an oil scraper, providing at least one electrode comprising zinc, arcing an electrical current through the at least one electrode such that a plasma comprising zinc is formed, and directing the plasma comprising zinc toward the oil scraper. Alternatively, the above steps may be performed in an inert atmosphere.

According to another embodiment of the present invention, a coated product or material may be formed by the steps of directing plasma comprising zinc toward at least one product or material. Further, the is process can be performed in an inert atmosphere. Additionally, it should be noted that plasma comprising zinc may be formed by providing at least one electrode comprising zinc and providing an electrical current to the at least one electrode. Further, at least one product or material may be presented under one or more electrodes by using a conveyor belt. At least one product or material may be comprised of an organic product or material or an inorganic product or material. Finally, the above steps may be performed in an inert atmosphere.

### BRIEF DESCRIPTION OF THE DRAWINGS

FIG. 1 is a partial diagrammatic view of one embodiment an engine oil system in accordance with the present invention.

FIG. 2 is a perspective view of a piston in accordance with the present invention.

FIG. 3 is a bottom plan view of the combined acid and oil filter of the embodiment of FIG. 1.

FIG. 4 is a cutaway side view of the combined acid and oil filter of the embodiment of FIG. 1.

FIG. 5 is a partial perspective view of an alternative embodiment of a combined acid and oil filter according to the present invention without the outer casing.

FIG. 6 is a partial perspective view of one embodiment of a process for coating components with a plasma comprising zinc.

### DETAILED DESCRIPTION OF THE INVENTION

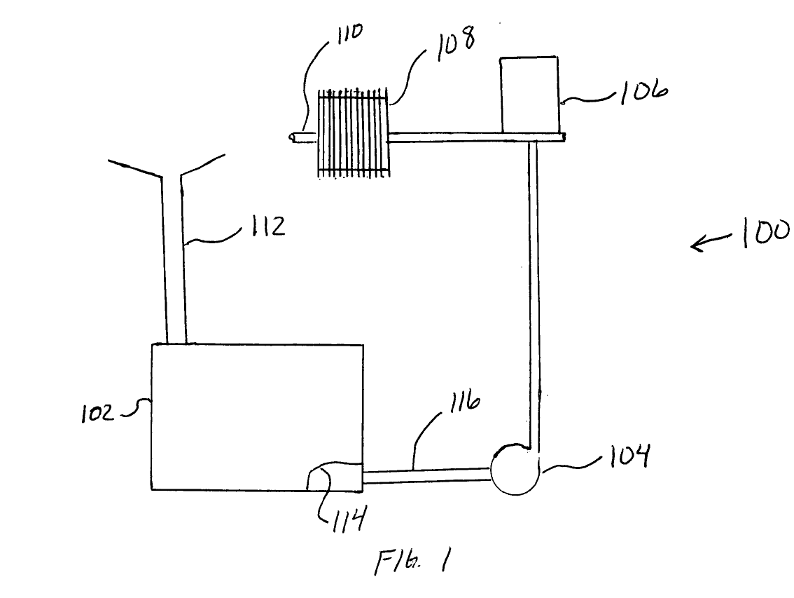

Referring to FIG. 1, one embodiment of the present invention is described. FIG. 1 shows a diagram of a typical engine oil system as improved according to the present invention. Oil system 100 comprises sump pan 102. Sump pan 102 is a removable metal chamber or bowl. Sump pan 102 is located at the bottom of the crankcase and provides for storage of the engine system oil. Typically, an oil drain plug is located at the bottom of this pan (not shown in FIG. 1) and can be removed to allow old oil to flow out of the vehicle during an oil change. In one embodiment of the present invention, sump pan 102 is made of zinc. Sump pan 102 thus comprises a multipurpose component as it also provides the function of an acid filter.

Sump pan 102 is connected to oil pump 104 through oil screen 114 and supply pipe 116. Oil screen 114 is a coarse-mesh metal screen that prevents foreign matter, such as lost washers, nuts and bolts, from entering oil pump 104. Oil is allowed to pass through oil screen 114 since it is a porous sheet. In one embodiment of the present invention, oil screen 114 is made of zinc. Oil screen 114 thus comprises a multipurpose component as it also provides the function of an acid filter.

Oil system 100 further comprises combined acid and oil filter 106, oil cooler 108, oil supply header 110, and oil return header 112.

In operation, oil sump pan 102 is partially filled with oil. Oil pump 104 creates a suction on oil sump pan 102. Large objects are kept from the suction of oil pump 104 by oil screen 114, which is also referred to as an oil pump strainer. Oil pump 104 forces oil through combined acid and oil filter 106 where small particles are filtered out of the oil. The oil then passes through oil cooler 108, where the temperature of the oil is controlled in a manner well known in the relevant art. After passing through oil cooler 108, the oil is supplied under pressure to lubricated parts through header 112. Oil from lubricated parts is returned to sump pan 102 through oil return header 112.

As an alternative to providing an oil screen 114 made of zinc, an oil screen 114 may be provided that is comprised of another material that is substantially coated with zinc. While it may be beneficial to completely cover an oil screen with zinc, it is not necessary to completely cover all surfaces of a screen, as the purpose is solely to provide interface between the zinc and oil. According to one method of coating an oil screen 114 with zinc, zinc is applied by directing a plasma spray of zinc onto the surface of oil screen 114. Plasma spray may be created by providing one or more electrodes comprising zinc in an optionally inert atmosphere, with an electric potential being created between the electrodes or between the electrode and a grounded portion. When the electrical potential between the electrodes becomes great enough, an arc is created between the electrodes, and zinc plasma is dispersed. The resulting plasma vapor may then be directed onto the surface of a material being conveyed under the electrodes, forming a fine zinc layer on the material. In this manner, an oil screen 114 of a given material can be coated with zinc and utilized in the same fashion as an oil screen 114 made of zinc.

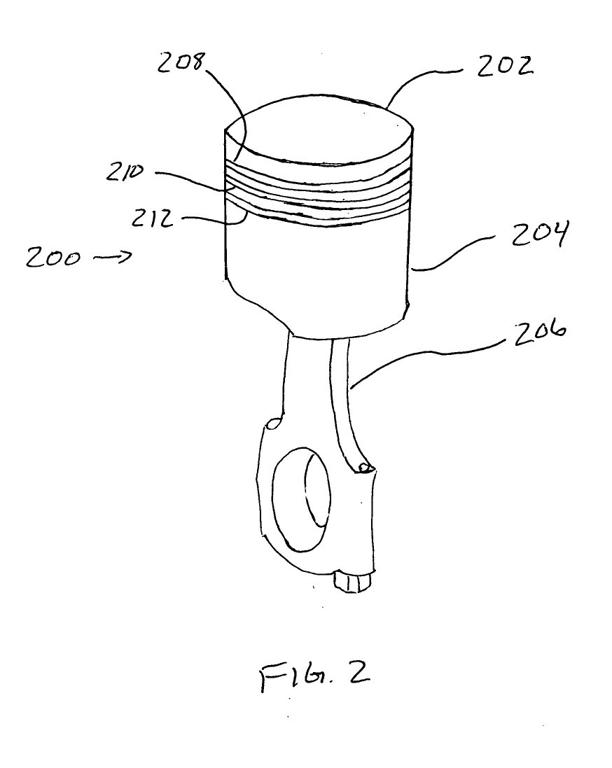

Referring now to FIG. 2, a perspective view of a piston ring is shown. Piston ring 200 comprises crown 202, skirt 204 and connecting rod 206. Also shown are seals 208 and 210 and oil scraper 212. Oil scraper 212 scrapes oil off of the cylinder wall, and returns it to sump pan 102 via small oil return holes in the piston (not shown) behind oil scraper 212. Thus, oil scraper 212 is considered herein to form a component in the oil system. In one embodiment of the present invention, oil scraper 212 is made from zinc. Oil scraper 212 thus comprises a multipurpose component as it also provides the function of an acid filter.

As an alternative to providing an oil scraper 102 made of zinc, an oil scraper 102 may be provided that is comprised of another metal or material, but substantially coated with zinc. While it may be beneficial to completely cover an oil scraper with zinc, it is not necessary to completely cover all surfaces of a scraper, as the purpose is solely to provide interface between the zinc and oil. According to one method of coating an oil scraper 102 with zinc, zinc is applied to another material by directing a plasma spray of zinc onto the surface of oil scraper 102. Plasma spray may be created by providing one or more electrodes comprising zinc in an optionally inert atmosphere, with an electric potential being created between the electrodes or one or more electrodes and a ground surface. When the electrical potential between the electrodes becomes great enough, an arc is created between the electrodes, and zinc plasma is dispersed. The resulting plasma vapor is then directed onto the surface of a material being conveyed under the electrodes, forming a zinc layer on the material. The zinc electrodes can be illustratively in the form of a strip or wire that are continuously fed outward from the electrical contacts to compensate for the erosion of zinc that occurs from the plasma creation. In this manner, an oil scraper 102 of a given material can be substantially coated with zinc and utilized in the same fashion as an oil scraper 102 made of zinc.

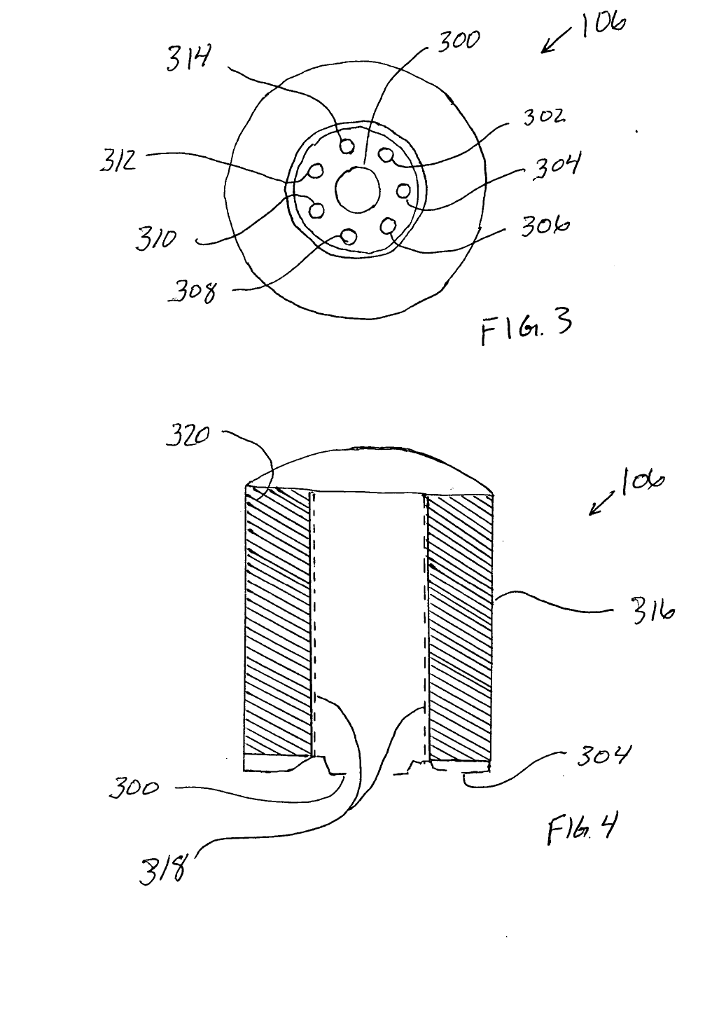

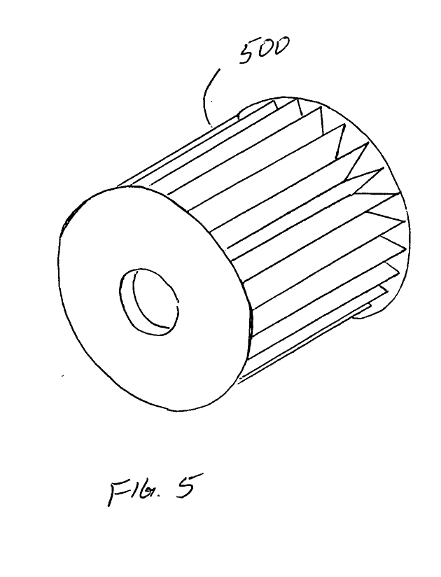

FIG. 3 shows a bottom plan view of multipurpose filter 106. Multipurpose filter 106 comprises supply port 300, and clean oil return ports 302, 304, 306, 308, 310, 312 and 314. With reference to FIG. 4, multipurpose filter 106 further comprises outer casing 316, inner screen 318 and filter batting 320. Both inner mesh 318 and filter batting 320 are made from porous sheets of material, allowing oil to flow from oil pump 104 through supply port 300, past inner mesh 318 and filter batting 320, and out to supply header 110 through clean oil return ports 302, 304, 306, 308, 310, 312 and 314.

According to one embodiment of the present invention, inner mesh 318 is made from zinc. While it may be beneficial to completely cover inner mesh 318 with zinc, it is not necessary to completely cover all surfaces of inner mesh 318, as the purpose is solely to provide interface between the zinc on inner mesh 318 and oil. Accordingly, as oil passes through inner mesh 318, acid products within the oil is neutralized by the zinc. Inner mesh 318 may be fabricated according to a variety of processes. For example, a sheet of zinc may be produced, and the punctured such that oil can pass through. Alternatively, a mat of metallic fibers, such as zinc fibers can be made according to processes known in the relevant art. Zinc fibers may be manufactured, by way of example, according the method of U.S. patent application Ser. No. 10/083,196, the teachings of which are incorporated herein by reference. Further, fibers or mesh of other materials may be coated with zinc using the zinc plasma spray process as described above and in the following description of FIG. 6, thereby creating a zinc coated inner mesh 318.

It will be appreciated that the product or materials coated with zinc in the embodiments of FIG. 1, FIG. 2, and FIG. 3 may be synthetic fibers such as polypropylene, polyethylene, nylon, rayon, polyester, polyamide, acrylic, or acrylonitrile. Further, natural fibers such as cellulose, cotton, hemp, jute, sisal, paper, and other similar materials may be used as the material coated with zinc. Generally, the product or material must have the characteristic of permitting the zinc to coat the same by the plasma coating method described herein.

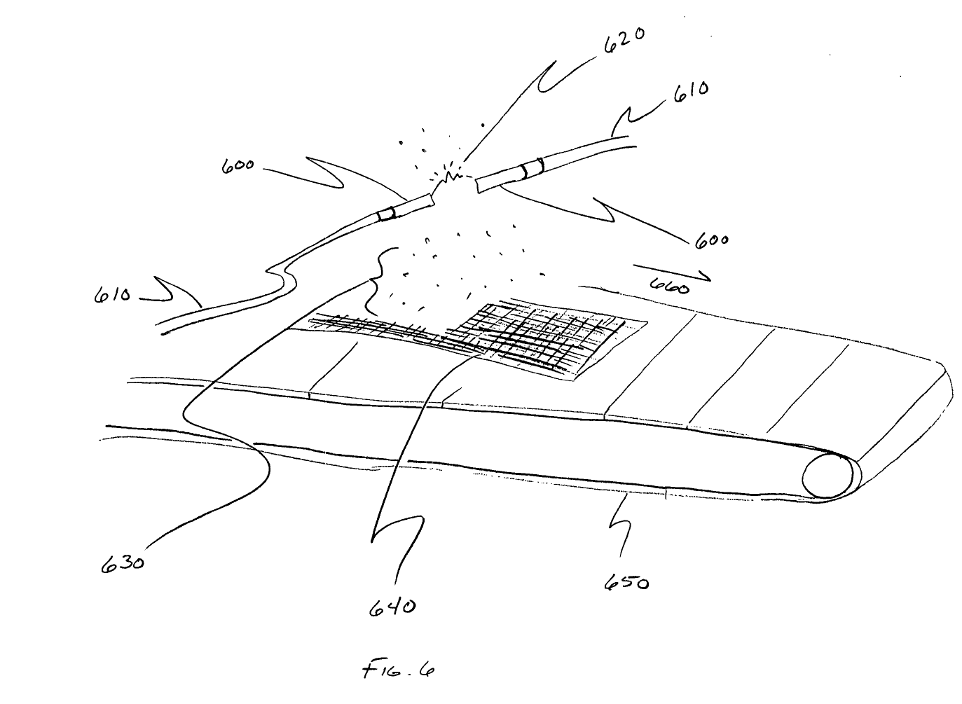

Those of skill in the art will appreciate that a number of variations of the present invention are possible. By way of example, but not of limitation, metal fibers may be incorporated into the porous filter material. The porous filter material may be a single sheet such as is shown in FIG. 4, it may be layered, or it may be in some other form such as a shaped sheet. With reference to FIG. 5, porous material 500 is shown as being shaped into a pleated form.

Moreover, the selection of the component or components to incorporate acid neutralizing metal may be varied. Additionally and/or alternatively, a component may be added to the engine oil system to provide an acid neutralizing component. By way of example, but not of limitation, an acid filter could be provided intermediate the oil filter and the rest of the oil system, such that the oil filter “piggybacks” onto the acid filter.

Additionally, a variety of metals and/or metal alloys may be used to provide the acid neutralizing metal of the present invention. By way of example, but not of limitation, the metal could comprise zinc, magnesium, cadmium, and/or calcium, or metal alloys thereof.

Accordingly, the present invention provides a component that will neutralize acid introduced into the engine oil. The present invention is compatible with existent oil systems and readily incorporated into new systems. The present invention is capable of being used without the need to introduce additional parts to existent oil systems. The present invention is also easily manufactured and need not add significantly to the cost of production of the component and/or oil system into which it is incorporated. Moreover, the present invention may be incorporated into a component that will typically not fracture or undergo other reduction under conditions likely to be encountered in, or close to, an internal combustion engine.

FIG. 6 illustrates a method for substantially coating components with zinc. This embodiment of the present invention comprises providing at least one electrode 600 comprising zinc that may be in the form of a strip or wire that can continue to be exposed as zinc is eroded. The at least one electrode 600 is attached to an electrical source such as electrical wires 610, which can be charged with enough current to create an arc 620 between at least one electrode 600 and either another electrode or a ground surface. When an arc is created with at least one electrode 600 comprising zinc, plasma particles 630 comprising zinc are formed. A component 640 such as a mesh, fiber, oil scraper, or other oil system component may be placed under the electrodes 630 or in another position such that the plasma particles settle on the surface of the component 640, or are conveyed to the component 640 by a flow of air or inert gas or by a separately applied electric field, causing a coating comprising zinc to form on component 640. Further, a conveyor belt 650 may be used to move component 640 (illustratively in direction 660) at a steady pace such that a plurality of components or their constituents have an even dispersion of plasma particles landing on their surface. Further, the speed of the conveyor belt and other factors such as manipulating the component while in the area of plasma spray will affect the thickness or completeness of the coating the component receives. It will be appreciated that the component may not need to be completely coated to produce the desired results. Finally, it should be noted that the above process can be performed in an inert atmosphere by utilizing a chamber to contain the above components, and filling the chamber with an inert gas such as a noble gas or other gas that will not oxidize the plasma particles. In this manner, each of the embodiments described above may be coated with zinc, regardless of the base composition of the component.

While the present invention has been described in detail with reference to certain exemplary embodiments thereof, such are offered by way of non-limiting example of the invention, as other versions are possible. Moreover, a number of design choices exist within the scope of the present invention, some of which have been discussed above. It is anticipated that a variety of other modifications and changes will be apparent to those having ordinary skill in the art and that such modifications and changes are intended to be encompassed within the spirit and scope of the invention as defined by the following claims.

1. A method comprising the steps of:
providing at least one electrode comprising zinc;
providing an electrical current to the at least one electrode comprising zinc such that a plasma comprising zinc is formed; and
directing the plasma toward a component of a combustible engine, the component operable to contact the oil in the combustible engine, such that the plasma comprising zinc coats the component.

2. The method of claim 1, wherein the component is an inner mesh, filter batting, oil screen, or oil scraper.

3. The method of claim 1 wherein the steps are performed in an inert atmosphere.

4. A coated oil screen created through the steps of:
providing an oil screen; and
directing a plasma comprising zinc toward the oil screen.

5. The coated oil screen of claim 4, wherein the steps are conducted in an inert atmosphere.

6. The coated oil screen of claim 5, wherein the zinc in plasma form is created by:
providing at least one electrode comprising zinc;
arcing an electrical current between the at least one electrode.

7. The zinc coated oil screen of claim 6, wherein the oil screen or a material to utilized in an oil screen is presented under the at least one electrode comprising zinc via a conveyor belt.

8. A coated oil screen created through the steps of:
providing a material used as an oil screen;
providing at least one electrode comprising zinc;
providing an electrical current to the at least on electrode such that a plasma comprising zinc is formed; and
directing the plasma comprising zinc toward the material used as an oil screen.

9. The coated oil screen of claim 8 wherein the steps coating the screen are performed in an inert atmosphere.

10. A coated oil scraper created through the steps of:
providing an oil scraper; and
directing a plasma comprising zinc toward the oil scraper.

11. The coated oil scraper of claim 10, wherein the steps are conducted in an inert atmosphere.

12. The coated oil scraper of claim 11, wherein the zinc in plasma form is created by:
providing at least one electrode comprising zinc; and
providing an electrical current to the at least one electrode so that a plasma comprising zinc is formed.

13. The coated oil scraper of claim 12, wherein the oil scraper is presented under the at least one electrode comprising zinc via a conveyor belt.

14. A coated oil scraper created through the steps of:
providing an oil scraper;
providing at least one electrode comprising zinc;
providing an electrical current to the at least one electrode such that a plasma comprising zinc is formed; and
directing the plasma comprising zinc toward the oil scraper.

15. The coated oil scraper of claim 14 wherein the steps are performed in an inert atmosphere.

16. A coated product or material formed by the steps of:
providing at least one product or material; and
directing a plasma comprising zinc toward the product or material.

17. The coated product or material of claim 16, wherein the steps are conducted in an inert atmosphere.

18. The coated product or material of claim 17, wherein the plasma comprising zinc is created by:
providing at least one electrode comprising zinc; and
providing an electrical current to the at least one electrode.

19. The coated product or material of claim 18, wherein the at least one product or material is presented under the at least one electrode comprising zinc via a conveyor belt.

20. The coated product or material of claim 19, wherein the at least one product or material comprises an organic product or material.

21. A coated product or material created through the steps of:
providing at least one product or material;
providing at least one electrode comprising zinc;
providing an electrical current to the at least one electrode such that a plasma comprising zinc is formed; and
directing the plasma comprising toward the at least one product or material.

22. The coated product or material of claim 21, wherein the steps are performed in an inert atmosphere.
